(19) United States
(12) Patent Application Publication
(10) Pub. No.: US 2008/0069377 A1
(43) Pub. Date: Mar. 20, 2008

(54) AUDIO PROCESSING SYSTEM AND METHOD

(75) Inventors: Shih-Fang Wong, Shenzhen (CN); Tsung-Jen Chuang, Shenzhen (CN); Jian-Lin Liu, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/617,697

(22) Filed: Dec. 28, 2006

(30) Foreign Application Priority Data
Sep. 15, 2006 (CN) 200610062609.7

(51) Int. Cl. H03G 5/00; H04R 29/00

(52) U.S. Cl. 381/98; 381/56

(57) ABSTRACT

An audio processing system includes an audio input apparatus, a frequency selecting unit, and an audio output apparatus. The audio input apparatus is used for receiving audio waves, and converting the audio waves to electric signals. The frequency selecting unit is used for filtering the electric signals, and generating filtered electric signals, the frequency selecting unit having adjustable passing-range. The audio output apparatus is used for converting the filtered electric signals into audible sound. An audio processing method for filtering inputted signals in a predetermined passing-range is also disclosed.

### BACKGROUND OF THE INVENTION

1. Field of the Invention

The present invention generally relates to audio processing systems and methods, and more particularly to a system and method for adjustably outputting audio signals in selected frequencies.

2. Description of Related Art

In noisy circumstances, isolators, such as earphones, are usually used for depressing or blocking noise, thus lightening hurts caused by the noise.

One kind of the earphones can detect frequency spectra of environmental noise, and generates anti-noise sound based on the detected frequency band. The anti-noise sound has an opposite phase to that of the environmental noise, thus counteracting the environmental noise.

However, this kind of earphone can not recognize useful sound and the noise, so that it is prone to counteract useful sound together with the environmental noise. For example, in a workshop, this kind of earphone can protect operators from being hurt by the noise caused by machines, but also prevents talks among the operators.

Therefore, an audio system and method are needed in the industry to adjustably passing selected audio frequencies.

### SUMMARY OF THE INVENTION

An audio processing system includes an audio input apparatus, a frequency selecting unit, and an audio output apparatus. The audio input apparatus is used for receiving audio waves, and converting the audio waves to electric signals. The frequency selecting unit is used for filtering the electric signals, and generating filtered electric signals, the frequency selecting unit having adjustable passing-range. The audio output apparatus is used for converting the filtered electric signals into audible sound.

A system includes a first unit for receiving and converting sound waves into electric signals; a second unit electrically coupled to the first unit, the second unit having adjustable passing-range for selecting a portion of the electric signals which has frequencies within the passing-range; and a third unit for converting the passed portion of the electric signals to audible sound.

An audio processing method includes following steps of: receiving sound from surroundings; converting the sound into electric signals; determining passing-range for the electric signals; passing a portion of the electric signals having frequencies within the passing-range; generating filtered electric signals; and converting the filtered electric signals into audible sound.

Other systems, methods, features, and advantages of the present audio processing system and method will be or become apparent to one with skill in the art upon examination of the following drawings and detailed description. It is intended that all such additional systems, methods, features, and advantages be included within this description, be within the scope of the present system and method, and be protected by the accompanying claims.

### BRIEF DESCRIPTION OF THE DRAWINGS

Many aspects of the present audio processing system and method can be better understood with reference to the following drawings. The components in the drawings are not necessarily to scale, emphasis instead being placed upon clearly illustrating the principles of the inventive system and method. Moreover, in the drawings, like reference numerals designate corresponding parts throughout the several views.

FIG. 1 is a block diagram of an audio processing system in accordance with a first exemplary embodiment;

FIG. 2 is a characteristic diagram showing a frequency-amplitude relationship according to a preferred example of the frequency selecting unit;

FIG. 3 is a block diagram of an audio processing system in accordance with a second exemplary embodiment; and

FIG. 4 is a flow chart describing an audio processing method in accordance with an exemplary embodiment.

### DETAILED DESCRIPTION OF THE INVENTION

Reference will now be made to the drawings to describe preferred embodiments of the present audio processing system and a preferred embodiment of the present audio processing method.

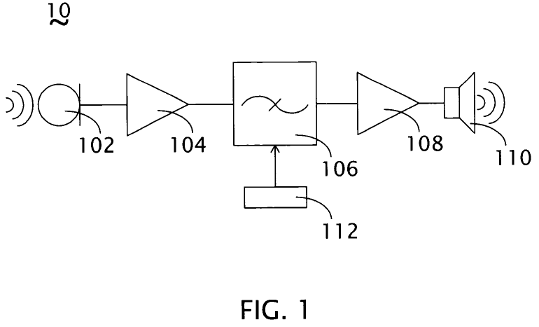

Referring to FIG. 1, a block diagram of an audio processing system in accordance with a first exemplary embodiment is illustrated. The audio processing system 10 includes an audio input apparatus 102, a preamplifier 104, a frequency-selecting unit 106, an amplifier 108, an audio output apparatus 110, and a frequency tuning unit 112.

The audio input apparatus 102 is used for receiving sound from surroundings, and converting the sound to electric signals. The electric signals are applied to the preamplifier 104. Preferably, the audio input apparatus 102 is a microphone.

The preamplifier 104 is used for amplifying and rectifying the electric signals, thereby yielding amplified electric signals, and sending the amplified electric signals to the frequency selecting unit 106.

The frequency selecting unit 106 is used for selectively passing portions of the amplified electrical signals from predetermined frequencies, thereby yielding passed electric signals. Preferably, the frequency selecting unit 106 is a filter having adjustable passing-range. The passed electric signals are then applied to the amplifier 108.

As an example, the frequency selecting unit 106 is adapted as a band-pass filter. An RCL filtering circuit with passing-range in a median frequency range may be chosen as the frequency selecting unit 106, two endpoints of the passing-range of is determined with a following equation:

$${f}_{1 , 2} = \sqrt{{( \frac{R}{2 L} )}^{2} + \frac{1}{LC}} ∓ \frac{R}{2 L} ,$$

wherein the R, C, L refers to a numeral value of a resister, capacitor, and inductor in the frequency selecting unit 106, respectively.

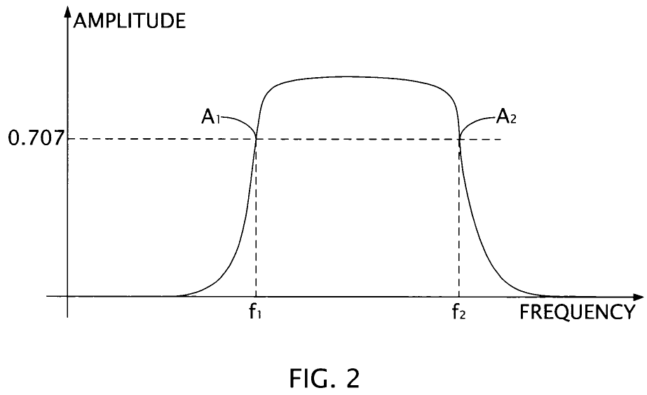

A characteristic diagram showing a frequency-amplitude relationship according to a preferred example of the frequency selecting unit 106 is illustrated in FIG. 2. The passing-range of the frequency selecting unit 106 is between f1 and f2, relative to two half-power points A1 and A2, respectively. Preferably, a frequency band between f1 and f2 is about 600 Hz to 1,000 Hz.

The amplifier 108 amplifies the passed electric signals to apply enough potential power, thereby yielding amplified signals for driving the audio output apparatus 110.

The audio output apparatus 110 is used for converting the amplified signals back to audio waves and outputting the audio waves. Preferably, the audio output apparatus 110 is a loudspeaker.

The frequency tuning unit 112 is used for receiving predetermined values to adjust the passing-range of the frequency selecting unit 106. When applied to the RCL filtering circuit as described above, the frequency tuning unit 112 may receive adjusted R, C, and L predetermined values for determining the two endpoints of the passing-range f1 and f2.

According to the audio processing system 10, users may selectively filter out unwanted frequency noises, and amplify predetermined frequency signals by adjusting the passing-range. The users may hear predetermined sounds with noises filtered out. For example, when in a classroom, students may adjust the audio processing system 10 to pass and amplify only teachers' voice in the environmental noise, thus achieving a high comprehensive environment.

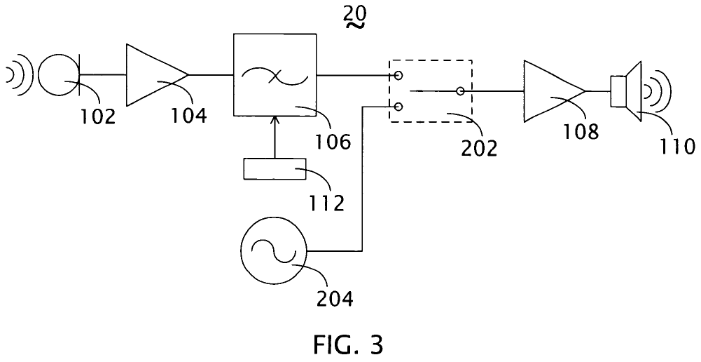

FIG. 3 illustrates a block diagram of an audio processing system in accordance with a second exemplary embodiment. The audio processing system 20 has generally a same structure as that of the audio processing system 10 as described in the first exemplary embodiment, both including the audio input apparatus 102, the preamplifier 104, the frequency selecting unit 106, the amplifier 108, the audio output apparatus 110, and the frequency tuning unit 112. In addition to the audio processing system 10, the audio processing system 20 may have two operational modes, such as a filter operational mode and an audio operational mode. In the filter operational mode, the audio processing system 20 can perform a filter operation that passes useful information and filters useless information. In the audio operational mode, the audio processing system 20 can playback music or radio.

The audio processing system 20 further includes an operational mode selection switch 202 and an audio signal source 204. The operational mode selection switch 202 has two input ends and an output end. The two input ends are connected to the frequency selecting unit 106 and the audio signal source 204, respectively. The output end is connected with the amplifier 108. The operational mode selection switch 202 is used for changing a mode of the audio processing system 20 between the filter operational mode and the playback operational mode. In the filter operational mode, the operational mode selection switch 202 connects the frequency selecting unit 106 with the amplifier 108, thus the audio processing system 20 filters out the environmental noise and amplifies sounds from a predetermined frequencies. In the playback operational mode, the operational mode selection switch 202 connects the audio signal source 204 with the amplifier 108, thus the audio processing system 20 receives an audio signal from the audio signal source 204 so as to reproduce music or radio. When the audio processing system 20 is used, if there is no need to filter out the environmental noise, it may be used for receiving signals from other audio sources, thus its functions may be duplicated.

The audio signal outputted from the audio signal source 204 may be signals from CDs, DVDs, or MP3 players, or signals from wireless communication apparatuses, such as radios or cellular phones.

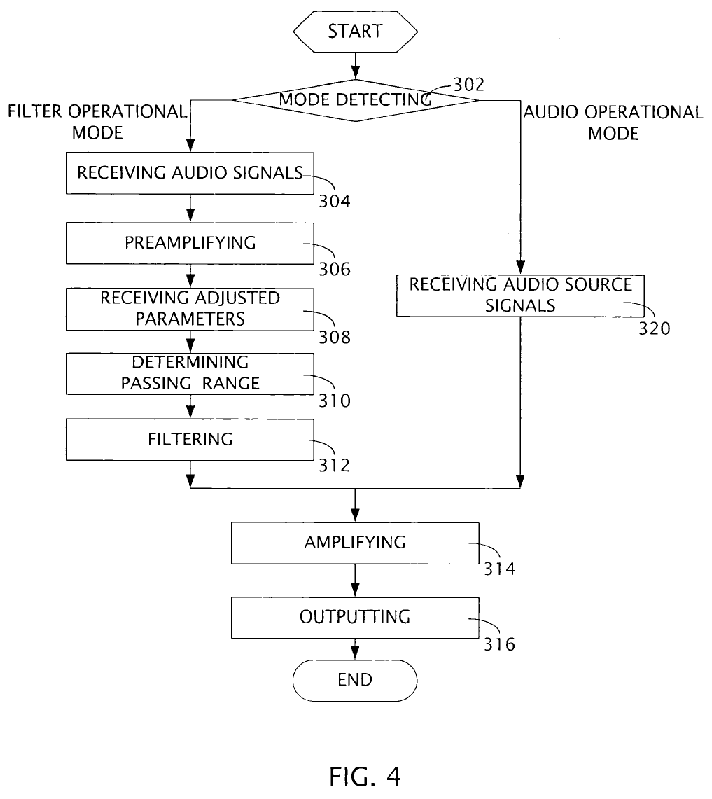

A flow chart describing an audio processing method in accordance with an exemplary embodiment with reference to the audio processing system 20 is illustrated in FIG. 4.

Firstly, the audio processing system 20 detects the operational mode of the 20 (step 302).

Secondly, if the audio processing system 20 is in the filter operational mode, the audio input apparatus 102 receives sound from surroundings, and converts the sound to electric signals that are to be applied to the preamplifier 104 (step 304).

Thirdly, the preamplifier 104 amplifies and rectifies the electric signals, and sends the amplified electric signals to the frequency selecting unit (step 306).

Next, the frequency tuning unit 112 receives predetermined values for parameters of the frequency selecting unit 106, thus adjusting passing-range of the frequency selecting unit 106. For example, in an RCL filtering circuit, the parameters may be a numeral value of a resister, capacitor, and inductor (step 308).

The frequency selecting unit 310 adjusts its passing-range according to the received values (step 310).

The frequency selecting unit 310 selectively passes a portion of the amplified electric signals from frequencies within the passing-range, and sends the passed portion of the electric signals to the amplifier 108 (step 312).

The amplifier amplifies the filtered electric signals that are sent by the frequency selecting unit 310, and sends the amplified signals to the audio output apparatus 110 (step 314).

The audio output apparatus 110 converts the amplified signals to audio waves, and outputs the audio waves that are to be heard by the users (step 316).

If, in the step 302 the audio processing system 20 detects that it is in the audio operational mode, the audio signal source 204 sends audio signals to the operational mode selection switch 202. And the audio signal is transmitted to the amplifier 108 through the operational mode selection switch 202 (step 320). Then, step 314 will be executed to amplify the audio signal; step 316 will be executed to convert the amplified signal to audio waves.

According to the audio processing method, the users may selectively filter unwanted frequency noises by adjusting particular parameters of the frequency selecting unit, further the passing filter band is adjusted. Users may use the audio processing method to pass and output predetermined frequencies with amplification. Thus, the users may hear predetermined frequency sound that is useful for information, instead of all frequency sound that contain lots of noise and useless information.

What is claimed is:

1. An audio processing system comprising:
an audio input apparatus for receiving audio waves, and converting the audio waves to electric signals;
a frequency selecting unit for filtering the electric signals, and generating filtered electric signals, the frequency selecting unit having adjustable passing-range;
an audio output apparatus for converting the filtered electric signals into audible sound.

2. The audio processing system as claimed in claim 1, further comprising a frequency tuning unit for receiving values to adjust parameters of the frequency selecting unit, the values defining the passing-range of the frequency selecting unit.

3. The audio processing system as claimed in claim 2, wherein the frequency selecting unit is an RCL filtering circuit, endpoints of the passing-range of which are determined by an equation:
$${f}_{1 , 2} = \sqrt{{( \frac{R}{2 L} )}^{2} + \frac{1}{LC}} ∓ \frac{R}{2 L} ,$$
wherein the R, C, and L respectively refer to numerical values of resisters, capacitors, and inductors in the RCL filtering circuit.

4. The audio processing system as claimed in claim 3, wherein the frequency tuning unit receives the values to adjust the R, C, and L.

5. The audio processing system as claimed in claim 1, further comprising a preamplifier, the preamplifier is connected between the audio input apparatus and the frequency selecting unit, for amplifying and rectifying the electric environmental signals.

6. The audio processing system as claimed in claim 1, further comprising an amplifier, the amplifier is connected between the frequency selecting unit and the audio output apparatus, for amplifying the filtered electric signals.

7. The audio processing system as claimed in claim 1, further comprising an operational mode selection switch and an audio signal source, the operational mode selection switch is used for adjustably connecting an audio signal source or the frequency selecting unit to the audio output apparatus.

8. The audio processing system as claimed in claim 8, further comprising an amplifier connected between the operational mode selection switch and the audio output apparatus.

9. A system comprising:
a first unit for receiving and converting sound waves into electric signals;
a second unit electrically coupled to the first unit, the second unit having adjustable passing-range for selecting a portion of the electric signals which has frequencies within the passing-range;
a third unit for converting the passed portion of the electric signals selected by the second unit to audible sound.

10. The system as claimed in claim 9, further comprising a fourth unit electrically coupled to the second unit for receiving inputted values that identify the passing-range of the second unit.

11. The system as claimed in claim 9, further comprising an audio signal source and a switch, the audio signal source being capable of playing audio information, the switch electrically coupled to the third unit and selectively electrically coupled to one of the second unit and the audio source, for allowing one of the audio information and the electric signals passed through the second unit to be transmitted to the third unit.

12. The system as claimed in claim 11, further comprising an amplifier, the amplifier electrically coupled to the switch, for amplifying the audio information and the electric signals passed through the second unit.

13. An audio processing method comprising the steps of:
receiving sound from surroundings;
converting the sound into electric signals;
determining passing-range for the electric signals;
passing a portion of the electric signals having frequencies within the passing-range;
generating passed electric signals; and
converting the passed electric signals into audible sound.

14. The audio processing method as claimed in claim 13, wherein the passing-range is between 600 Hz to 1000 Hz.

15. The audio processing method as claimed in claim 13, wherein an RCL filtering circuit is used to filter the electric signals, the RCL filtering circuit having adjustable passing-range.

16. The audio processing method as claimed in claim 15, wherein the determination of the passing-range comprises steps of:
receiving numeral values of resisters, capacitors, and inductors in the RCL filtering circuit;
determining endpoints of the passing-range by an equation:
$${f}_{1 , 2} = \sqrt{{( \frac{R}{2 L} )}^{2} + \frac{1}{LC}} ∓ \frac{R}{2 L} ,$$
the R, C, and L respectively referring to numeral values of resisters, capacitors, and inductors in the RCL filtering circuit.

17. The audio processing method as claimed in claim 13, further comprising the step of:
amplifying and rectifying the electric signals.

18. The audio processing method as claimed in claim 13, further comprising the step of:
amplifying the passed electric signals.

19. The audio processing method as claimed in claim 13, further comprising the steps of:
detecting an operating operational mode;
receiving audio source signals; converting the audio source signals into audio waves; and
outputting the audio waves.

20. The audio processing method as claimed in claim 19, further comprising the step of: amplifying the audio source signals.
